(19) United States
(12) Patent Application Publication
(10) Pub. No.: US 2026/0243408 A1
(43) Pub. Date: Aug. 20, 2026

(54) LIGHT EMITTING DEVICE, IMAGE FORMING DEVICE, DISPLAY DEVICE, PHOTOELECTRIC CONVERSION DEVICE, ELECTRONIC APPARATUS, AND WEARABLE DEVICE

(71) Applicant: CANON KABUSHIKI KAISHA, Tokyo (JP)

(72) Inventor: SHOMA HINATA, Kanagawa (JP)

(21) Appl. No.: 19/535,299

(22) Filed: Feb. 10, 2026

(30) Foreign Application Priority Data
Feb. 20, 2025 (JP) 2025-026029

(51) Int. Cl. F21V 5/04; H10H 20/854; H10H 20/855

(52) U.S. Cl. CPC F21V 5/045; F21V 5/04; H10H 20/854; H10H 20/855

(57) ABSTRACT

A device including a light emitting element arranged on a surface of a substrate and including a light emitting portion and a lens, and an optical member where light transmitted through the lens enters is provided. In an orthogonal projection onto the surface, a length of the optical member in a first direction is shorter than that of the optical member in a second direction orthogonal to the first direction, in a virtual section along the first direction and passing through a vertex of the lens, a light flux emitted from the light emitting portion and transmitted through the lens includes light rays which enter one end and another end of the optical member in the first direction, and a length of the light emitting portion in the first direction is shorter than that of the light emitting portion in the second direction.

### BACKGROUND

### Field of the Technology

The present disclosure relates to alight emitting device, an image forming device, a display device, a photoelectric conversion device, an electronic apparatus, and a wearable device.

### Description of the Related Art

Japanese Patent Laid-Open No. 2022-114845 describes that, by arranging a microlens on a light emitting portion and adjusting the size and shape of the light emitting portion, the ratio of light contributing to display is increased, thereby reducing power consumption.

To improve the performance of a light emitting device, it is necessary to further reduce the power consumption of the light emitting device. A light emitting device can include various components in accordance with the purpose of use, specifications, and the like. By adjusting the shape of a light emitting portion in accordance with the components included in the light emitting device, the ratio of light not contributing to display can be reduced, thereby further reducing power consumption.

### SUMMARY

Some embodiments of the present disclosure provide a technique advantageous in reduction of power consumption.

According to some embodiments, a light emitting device comprising: a substrate; and a light emitting element which is arranged on a main surface of the substrate and includes a light emitting portion including an organic layer and a lens arranged on the light emitting portion, wherein the device further comprises, on a light extraction side of the light emitting element, an optical member where light transmitted through the lens enters, in an orthogonal projection onto the main surface, a length of the optical member in a first direction is shorter than a length of the optical member in a second direction orthogonal to the first direction, in a virtual section along a normal direction of the main surface and the first direction and passing through a vertex of the lens, a light flux emitted from the light emitting portion and transmitted through the lens includes light rays which enter one end portion and the other end portion, respectively, of the optical member in the first direction, and in an orthogonal projection onto the main surface, a length of the light emitting portion in the first direction is shorter than a length of the light emitting portion in the second direction, is provided.

Features of the present disclosure will become apparent from the following description of embodiments with reference to the attached drawings. The following description of embodiments is described by way of example.

### BRIEF DESCRIPTION OF THE DRAWINGS

FIG. 1 is a view showing an example of the arrangement of a light emitting device according to an embodiment;

FIG. 2 is a view showing an example of the arrangement of the light emitting device according to the embodiment;

FIG. 3 is a view showing an example of the arrangement of the light emitting device according to the embodiment;

FIG. 4 is a view showing an example of the arrangement of the light emitting device according to the embodiment;

FIG. 5 is a view showing an example of an effect of the light emitting device according to the embodiment;

FIG. 6 is a view showing an example of an effect of the light emitting device according to the embodiment;

FIG. 7 is a view showing an example of the arrangement of the light emitting device according to the embodiment;

FIG. 8 is a view showing an example of the arrangement of the light emitting device according to the embodiment;

FIG. 9 is a view showing an example of the arrangement of the light emitting device according to the embodiment;

FIG. 10 is a view showing an example of the arrangement of the light emitting device according to the embodiment;

FIGS. 11A to 11C are views showing an example of an image forming device using the light emitting device according to the embodiment;

FIG. 12 is a view showing an example of a display device using the light emitting device according to the embodiment;

FIG. 13 is a view showing an example of a photoelectric conversion device using the light emitting device according to the embodiment;

FIG. 14 is a view showing an example of an electronic apparatus using the light emitting device according to the embodiment;

FIGS. 15A and 15B are views each showing an example of a display device using the light emitting device according to the embodiment;

FIG. 16 is a view showing an example of an illumination device using the light emitting device according to the embodiment;

FIGS. 17A and 17B are views showing an example of a moving body using the light emitting device according to the embodiment; and

FIGS. 18A and 18B are views each showing an example of a wearable device using the light emitting device according to the embodiment.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

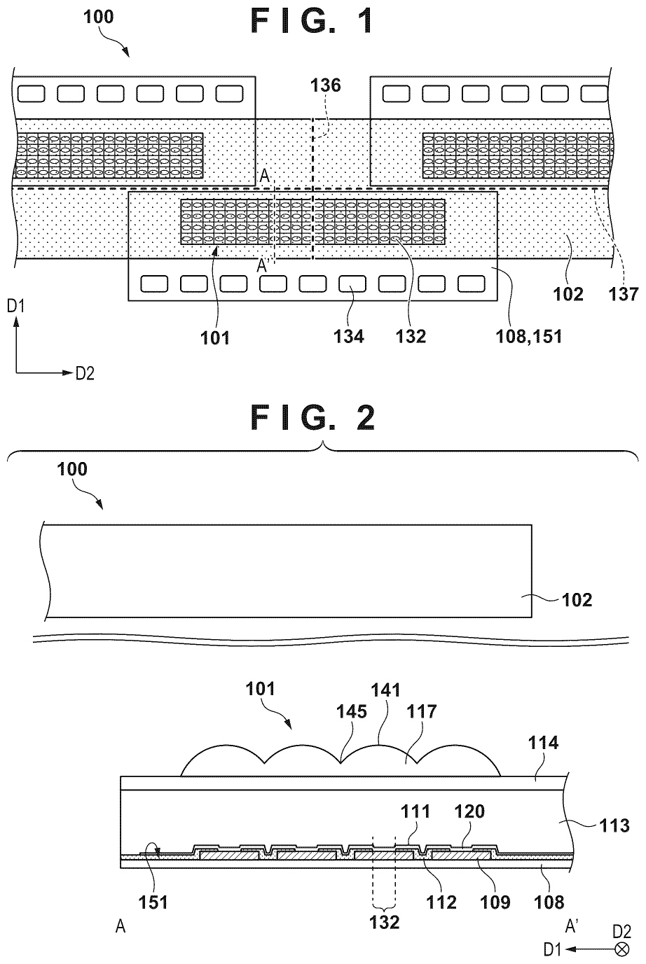

With reference to FIGS. 1 to 10, a light emitting device according to the present disclosure will be described. FIGS. 1 and 2 are views showing an example of the arrangement of apart of alight emitting device 100 according to this embodiment. More specifically, FIG. 1 is an orthogonal projection view of the light emitting device 100 when viewed in a direction (normal direction) perpendicular to a main surface 151 of a substrate 108 constituting the light emitting device 100. FIG. 2 is a sectional view taken along a line A-A′ in FIG. 1.

The light emitting device 100 includes the substrate 108, a light emitting element 101 including a light emitting portion 132 arranged on the main surface 151 of the substrate 108 and a lens 117 arranged above the light emitting portion 132, and a plurality of pads 134 for electrical connection to the outside of the light emitting device 100. The light emitting element 101 includes one light emitting portion 132 and one lens 117 arranged to correspond to the light emitting portion 132. The example shown in FIGS. 1 and 2 shows an organic light emitting element that includes, as the light emitting portion 132, an electrode 109 (to be also referred to as a lower electrode or the like), an organic layer 120 including a light emitting layer, and an electrode 111 (to be also referred to as an upper electrode or the like). However, the present disclosure is not limited to this and, for example, a light emitting element that contains, as the light emitting portion 132, an inorganic light emitting material or quantum dots may be used, or a light emitting diode or the like may be used. For example, a so-called micro LED may be used as the light emitting portion 132. Details of the light emitting element 101 and components of the light emitting element 101 such as an insulating layer 112, a protective layer 113, and a planarizing layer 114 will be described later.

The light emitting device 100 further includes, on the light extraction side of the light emitting element 101, an optical member 102 where light transmitted through the lens 117 enters. The optical member 102 transmits light emitted from the light emitting element 101, and may have a function of condensing, diffusing, imaging, or projecting the light. For example, when used as an exposure device of an image forming device, the light emitting device 100 may have a function of condensing light emitted from the light emitting element 101 onto the surface of a photosensitive member. In that case, the optical member 102 may be an erect equal-magnification lens array that images light emitted from the light emitting element 101 on the surface of the photosensitive member in an erect equal-magnification manner. In this embodiment, as shown in FIG. 1, in the orthogonal projection onto the main surface 151 of the substrate 108, the length of the optical member 102 in a direction D1 is shorter than the length in a direction D2 orthogonal to the direction D1. The length of the optical member 102 in the direction D1 may be, for example, 0.1 mm or more and 10 mm or less. The length of the optical member 102 in the direction D2 may be, for example, 100 mm or more and 2,000 mm or less.

Here, the length of the optical member 102 in the direction D1 can be defined as a distance between two intersections of a virtual straight line 136, which passes through the center of the optical member 102 and is parallel to the direction D1, with the outer edge of the optical member 102 in the orthogonal projection onto the main surface 151 of the substrate 108. Similarly, the length of the optical member 102 in the direction D2 can be defined as a distance between two intersections of a virtual straight line 137, which passes through the center of the optical member 102 and is parallel to the direction D2, with the outer edge of the optical member 102 in the orthogonal projection onto the main surface 151 of the substrate 108. The center of the optical member 102 in the orthogonal projection onto the main surface 151 of the substrate 108 can be defined as the geometric centroid position of the planar shape of the outer edge of the optical member 102 in the orthogonal projection onto the main surface 151 of the substrate 108. In the arrangement shown in FIG. 1, in the orthogonal projection onto the main surface 151 of the substrate 108, the length of the optical member 102 passing through the center of the optical member 102 has a minimum value in the direction D1. In the orthogonal projection onto the main surface 151 of the substrate 108, the length of the optical member 102 passing through the center of the optical member 102 has a maximum value in the direction D2. In the arrangement shown in FIG. 1, the virtual straight lines 136 and 137 are symmetry axes of the shape of the outer edge of the optical member 102, but need not necessarily be the symmetry axes.

Next, in the orthogonal projection onto the main surface 151 of the substrate 108, the outer edge of the optical member 102 can be defined as the outer edge of a region of the optical member 102 where light emitted from the light emitting element 101 is transmitted. When the optical member 102 includes a plurality of lens elements arranged adjacent to each other, such as a lens array, one polygon that encloses the plurality of lens elements and circumscribes the outermost lens element may be defined as the outer edge of the optical member 102. Here, the polygon may be, for example, a quadrangle. The optical member 102 may be arranged spaced apart from the lens 117 of the light emitting element 101. In that case, the region between the optical member 102 and the lens 117 of the light emitting element 101 may be, for example, a space where a gas such as air exists. Alternatively, for example, a transparent resin or the like may be arranged in the region between the optical member 102 and the lens 117 of the light emitting element 101. The distance between the optical member 102 and the lens 117 of the light emitting element 101 in a direction perpendicular to the main surface 151 of the substrate 108 may be, for example, 1 mm or more and 50 mm or less.

The lens 117 can also be called a microlens or the like. The surface (to be also referred to as the upper surface or the like) of the lens 117 has a convex shape in a direction away from the main surface 151 of the substrate 108. It can also be said that the upper surface of the lens 117 has a convex shape toward the optical member 102. Light emitted in an outward direction (a direction away from the center of the light emitting portion 132 in the direction perpendicular to the main surface 151 of the substrate 108) from the light emitting portion 132 can be converted into parallel light (collimated light) by refraction at the surface of the lens 117, and extracted in a direction (front direction) perpendicular to the main surface of the substrate 108. That is, the lens 117 can function as a collimator. The lens 117 may have a light condensing property. The lens 117 can have positive power for converting light emitted from the light emitting portion 132 into parallel light or convergent light. The lens 117 may have, for example, a convex shape in a direction toward the light emitting portion 132. However, in that case, an air layer or the like for generating a difference in refractive index from the lens 117 can be necessary between the lens 117 and the planarizing layer 114 and the like (the planarizing layer 114 and the like will be described later) on the light emitting portion 132. Accordingly, the distance between the light emitting portion 132 and the lens 117 needs to be large. In this embodiment, the surface of the lens 117 has a convex shape in the direction away from the main surface 151 of the substrate 108. Therefore, it becomes possible for the lens 117 to be directly arranged as shown in FIG. 2. As a result, the light emitting device 100 can be miniaturized.

The lens 117 includes a vertex 141. The vertex 141 of the lens 117 can be, for example, a portion of the surface of the lens 117 that is furthest from the main surface 151 of the substrate 108. Alternatively, the vertex 141 of the lens 117 may be, for example, a set of points where the distance from the main surface 151 of the substrate 108 is maximal. Furthermore, the vertex 141 of the lens 117 can be, for example, a portion of the surface of the lens 117 where the tangent thereof is parallel to the main surface 151 of the substrate 108. FIG. 2 shows a section passing through the vertex 141 of the lens 117 and taken along the normal direction of the main surface 151 of the substrate 108. Here, the distance between the optical member 102 and the vertex 141 of the lens 117 in the normal direction of the main surface 151 of the substrate 108 can be larger than the distance between the vertex 141 of the lens 117 and the light emitting portion 132 in the normal direction of the main surface 151 of the substrate 108.

When the lenses 117 arranged to respectively correspond to the light emitting elements 101 adjacent to each other are formed independently, an outer edge 145 of the lens 117 is the outermost peripheral portion of the lens 117. When the lenses 117 arranged to respectively correspond to the light emitting elements 101 adjacent to each other are formed to be at least partially continuous as shown in FIG. 2, the outer edge 145 of the lens 117 may be, for example, a set of points where the distance between the surface of the lens 117 and the main surface 151 of the substrate 108 is minimal. For example, the outer edge 145 of the lens can be a portion where the tangent of the surface of the lens 117 is parallel to the main surface 151 of the substrate 108 between the light emitting elements 101 adjacent to each other. A region surrounded by the outer edge 145 can be defined as one lens 117. The geometric centroid of the planar shape of the outer edge 145 in the orthogonal projection onto the main surface 151 of the substrate 108 can be defined as the center of the lens 117. In the orthogonal projection onto the main surface 151 of the substrate 108, the vertex 141 of the lens 117 and the center of the lens 117 may be arranged at the same position, or may be arranged at different positions.

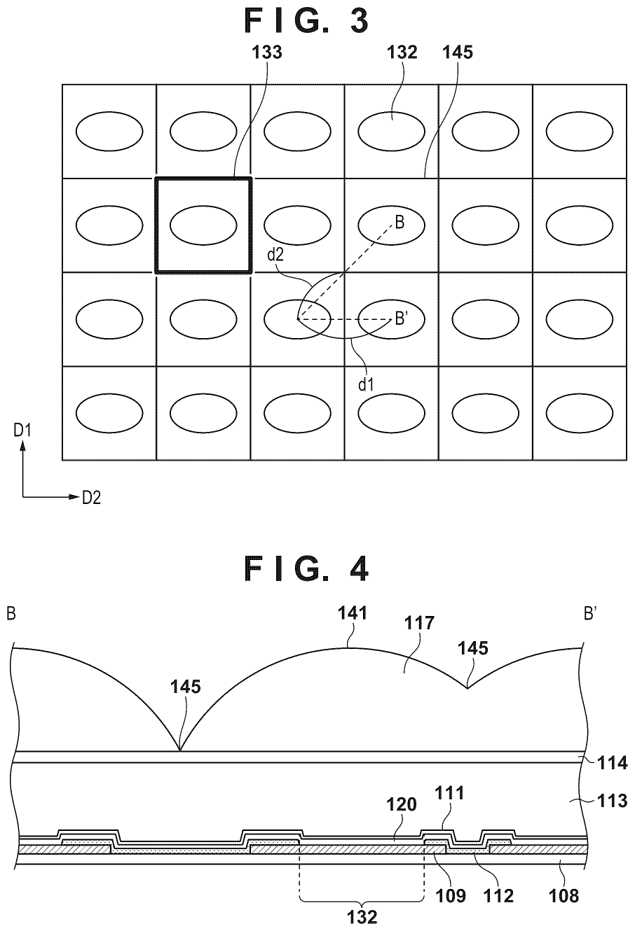

FIG. 3 is a plan view focusing on the outer edge 145 of the lens 117 and the light emitting portion 132 in the orthogonal projection onto the main surface 151 of the substrate 108. FIG. 4 is a schematic view showing a section taken along a line B-B′ in FIG. 3. In the example shown in FIG. 3, the outer edge 145 of the lens 117 has a square shape.

The length of the lens 117 in the direction D1 can be defined as a distance between two intersections of a virtual straight line, which passes through the center of the lens 117 and is parallel to the direction D1, with the outer edge 145 of the lens 117 in the orthogonal projection onto the main surface 151 of the substrate 108. Similarly, the length of the lens 117 in the direction D2 can be defined as a distance between two intersections of a virtual straight line, which passes through the center of the lens 117 and is parallel to the direction D2, with the outer edge 145 of the lens 117 in the orthogonal projection onto the main surface 151 of the substrate 108. The center of the lens 117 in the orthogonal projection onto the main surface 151 of the substrate 108 can be defined as the geometric centroid position of the planar shape of the outer edge 145 in the orthogonal projection onto the main surface 151 of the substrate 108.

When a plurality of light emitting portions 132 are arranged on the substrate 108, a region surrounded by perpendicular bisectors each between centers of the light emitting portions 132 adjacent to each other can be defined as a unit pixel 133 corresponding to one light emitting element 101. FIG. 3 illustrates one of the unit pixels 133. In the example shown in FIG. 3, the unit pixel 133 has a square shape, and one unit pixel 133 includes one light emitting portion 132. The outer edge 145 of the lens 117 matches the outer edge of the unit pixel 133. The outer edge of the unit pixel 133 may be, for example, a polygon formed by connecting points where the distance from the centroid of the lower electrode of one pixel to the centroid of the lower electrode of the pixel adjacent to the one pixel is shortest in the orthogonal projection onto the main surface 151 of the substrate 108. From a viewpoint of improving the light extraction efficiency using the lens 117, the area of the lens 117 in the orthogonal projection onto the main surface 151 of the substrate 108 may be increased. Therefore, the area of the unit pixel 133 occupied by the lens 117 may be increased, and the shape of the outer edge 145 of the lens 117 may be the same as the shape of the unit pixel 133. The shape of the outer edge 145 of the lens 117 may be analogous to the unit pixel 133. On the other hand, as will be described later, to reduce power consumption, in the orthogonal projection onto the main surface 151 of the substrate 108, the shape of the outer edge of the light emitting portion 132 is not analogous to the shape of the outer edge of the unit pixel 133 including the light emitting portion 132. Hence, in the orthogonal projection onto the main surface 151 of the substrate 108, the shape of the outer edge of the light emitting portion 132 is not analogous to the shape of the outer edge 145 of the lens 117.

From another viewpoint, as shown in FIG. 3, let d1 be the shortest distance between the centers of the light emitting portions 132 arranged in the light emitting elements 101 (unit pixels 133) adjacent to each other, and d2 be the longest distance from the center to the outer edge 145 in the lens 117. In this case, a relationship expressed by

$$d 1 / 2 < d 2 \qquad ( 1 )$$

may be satisfied. By satisfying the relationship expressed by inequality (1), the area of the unit pixel 133 occupied by the lens 117 can be increased. Accordingly, the light extraction efficiency can be improved.

The light emitting portion 132 in this embodiment has a shape with the length in the direction D1 shorter than the length in the direction D2 orthogonal to the direction D1 in the orthogonal projection onto the main surface 151 of the substrate 108. Here, the length of the light emitting portion 132 in the direction D1 can be defined as a distance between two intersections of a virtual straight line, which passes through the center of the light emitting portion 132 and is parallel to the direction D1, with the outer edge of the light emitting portion 132 in the orthogonal projection onto the main surface 151 of the substrate 108. Similarly, the length of the light emitting portion 132 in the direction D2 can be defined as a distance between two intersections of a virtual straight line, which passes through the center of the light emitting portion 132 and is parallel to the direction D2, with the outer edge of the light emitting portion 132 in the orthogonal projection onto the main surface 151 of the substrate 108. The center of the light emitting portion 132 in the orthogonal projection onto the main surface 151 of the substrate 108 can be defined as the geometric centroid position of the planar shape of the outer edge of the light emitting portion 132 in the orthogonal projection onto the main surface 151 of the substrate 108. In the arrangement shown in FIG. 3, in the orthogonal projection onto the main surface 151 of the substrate 108, the length of the light emitting portion 132 passing through the center of the light emitting portion 132 has a minimum value in the direction D1. In the orthogonal projection onto the main surface 151 of the substrate 108, the length of the light emitting portion 132 passing through the center of the light emitting portion 132 has a maximum value in the direction D2.

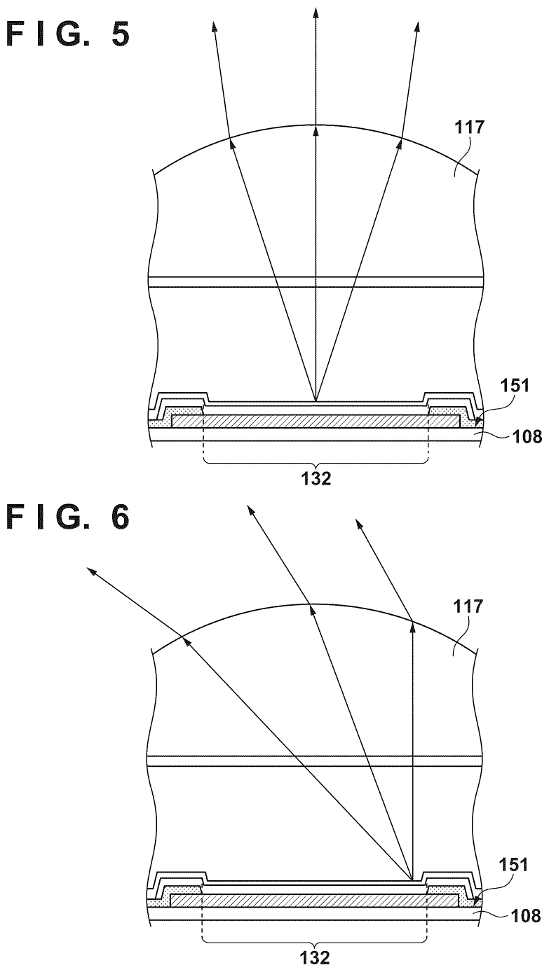

The effect of forming the light emitting portion 132 in a shape where the length in the direction D1 is shorter than the length in the direction D2 will be described below. FIGS. 5 and 6 are schematic views for explaining light rays emitted from the light emitting portion 132, refracted at the surface of the lens 117, and extracted. FIG. 5 shows light rays emitted from near the center of the light emitting portion 132, and FIG. 6 shows light rays emitted from near the outer periphery of the light emitting portion 132. As shown in FIG. 5, light emitted from near the center of the light emitting portion 132 is refracted in the normal direction with respect to the main surface 151 of the substrate 108. On the other hand, as shown in FIG. 6, light emitted from near the outer periphery of the light emitting portion 132 is refracted in an oblique direction with respect to the main surface 151 of the substrate 108. Defining an angle formed by the light ray refracted at the surface of the lens 117 and extracted and a perpendicular line to the main surface 151 of the substrate 108 as a radiation angle, it can be said that light emitted from near the outer periphery of the light emitting portion 132 has a larger radiation angle than light emitted from near the center.

The fact that light emitted from near the outer periphery of the light emitting portion 132 has a larger radiation angle than light emitted from near the center can also be understood from the following explanation. Contrary to the above explanation, consider a light ray that enters from the light extraction side of the lens 117 toward the lens 117 in a direction perpendicular to the main surface 151 of the substrate 108. In this case, the lens 117 has a light condensing effect, so that the light ray reaches near the center of the light emitting portion 132. On the other hand, a light ray that enters the lens 117 obliquely with an inclination from the direction perpendicular to the main surface 151 of the substrate 108 reaches near the outer periphery of the light emitting portion 132. The larger the inclination from the direction perpendicular to the main surface 151 of the substrate 108, the farther the position where the light ray reaches is from the center of the light emitting portion 132. Since a light ray travels the same optical path even from the opposite side, it is understood that light emitted from the outer region of the light emitting portion 132 is extracted with an inclination from the normal direction with respect to the main surface 151 of the substrate 108.

As described above, the length of the optical member 102 in the direction D1 is shorter than the length of the optical member 102 in the direction D2 orthogonal to the direction D1. Therefore, the radiation angle of light capable of transmission through the optical member 102 in the direction D1 is smaller than the radiation angle of light capable of transmission through the optical member 102 in the direction D2. In a case where the light emitting portion 132 has a shape where the length in the direction D1 is equal to the length in the direction D2, the radiation angle is the same in the direction D1 and the direction D2. Then, in the direction D1, some light rays may not be transmitted through the optical member 102. In this case, by shortening the length of the light emitting portion 132 in the direction D1, the amount of light with a large radiation angle in the direction D1 decreases, so that light components not transmitted through the optical member 102 can be reduced. Since the area of the light emitting portion 132 can be reduced while keeping the amount of light transmitted through the optical member 102, by making the length of the light emitting portion 132 in the direction D1 smaller than the length in the direction D2, an effect of reducing power consumption can be achieved.

From another viewpoint, it can be understood that the larger the difference between the length of the lens 117 and the length of the light emitting portion 132, the more the amount of light having a large radiation angle can be reduced. In the example shown in FIGS. 1 to 4, in the orthogonal projection onto the main surface 151 of the substrate 108, the difference between the length of the lens 117 in the direction D1 and the length of the light emitting portion 132 in the direction D1 is larger than the difference between the length of the lens 117 in the direction D2 and the length of the light emitting portion 132 in the direction D2. By satisfying this relationship, power consumption can be reduced.

As the length of the light emitting portion 132 in the direction D1 decreases, the radiation angle in the direction D1 becomes small. The length of the light emitting portion 132 in the direction D1 may be set such that, in a virtual section along the normal direction of the main surface 151 of the substrate 108 and the direction D1 and passing through the vertex of the lens 117, a light flux emitted from the light emitting portion 132 and transmitted through the lens 117 includes light rays which enter one end portion and the other end portion, respectively, of the optical member 102 in the direction D1. More specifically, for example, assume that the length of the optical member 102 in the direction D1 is 1 mm, and the distance between the optical member 102 and the lens 117 of the light emitting element 101 in the direction perpendicular to the main surface 151 of the substrate 108 is 4 mm. Also, assume that the distance in the direction D2 between the virtual straight line 137 of the optical member 102 parallel to the direction D2 (as described above, the virtual straight line 137 can be the symmetry axis in the planar shape of the outer edge of the optical member 102) and the center of the light emitting portion 132 is 0.2 mm. In this case, from calculation, the radiation angle of a light ray traveling toward one end portion of the optical member 102 in the direction D1 is about 4°, and the radiation angle of a light ray traveling toward the other end portion is 10°. Hence, the length of the light emitting portion 132 in the direction D1 may be set such that, when tracing light rays emitted from the light emitting portion 132 and refracted at the interface between different materials according to Snell's law, as shown in FIGS. 5 and 6, there are light rays having a radiation angle of 4° and light rays having a radiation angle of 100 or more. Here, there may be a case where light emitted from the light emitting portion 132 and transmitted through the lens 117 passes only between both ends of the optical member 102 in the direction D1. However, in this case, the optical member 102 is large in the direction D1 more than necessary, and the light emitting device 100 can become large.

From another viewpoint, a condition for the existence of light rays emitted from the light emitting portion 132, passing through the lens 117, and reaching the both end portions of the optical member 102 in the direction D1 can also be understood that light rays entering from both end portions of the optical member 102 toward the lens 117 and refracted reach the light emitting portion 132. More specifically, in the same example as described above, a condition for the existence of light rays reaching the both end portions of the optical member 102 in the direction D1 is that light rays entering the lens 117 from the light extraction side at angles of 4° and 10°, respectively, which correspond to the radiation angles of the light rays, reach within the light emitting portion 132.

The arrangement shown in FIGS. 1 to 6 shows an example where the light emitting portion 132 has an elliptical shape. However, the present disclosure is not limited to this as long as the length in the direction D1 is shorter than the length in the direction D2 in accordance with the shape of the optical member 102. In the orthogonal projection onto the main surface 151 of the substrate 108, the shape of the light emitting portion 132 may be a polygon such as a rectangle, a diamond, or a parallelogram, or may be a polygon with rounded (chamfered) corners. From another viewpoint, the shape of the light emitting portion 132 may be a line-symmetric shape with only two symmetry axes, and the two symmetry axes may be parallel to the direction D1 and the direction D2, respectively. More specifically, as shown in FIG. 3, the light emitting portion 132 may have an elliptical shape with the minor axis parallel to the direction D1 and the major axis parallel to the direction D2. As another example, the light emitting portion 132 may have a rectangular shape with two short sides parallel to the direction D1 and two long sides parallel to the direction D2. For example, in the orthogonal projection onto the main surface 151 of the substrate 108, the outer edge of each of the optical member 102 and the light emitting portion 132 may have a planar shape where the length has a minimum value in the direction D1. Alternatively, in the orthogonal projection onto the main surface 151 of the substrate 108, the outer shape of the light emitting portion 132 may be two-fold rotationally symmetric and not possess rotational symmetry of three times or more. By forming the light emitting portion 132 in the shape described above, it is possible to enhance the symmetry of radiation angle characteristics in each of the direction D1 and the direction D2 while reducing power consumption. As another example, there can be a case where the distance in the direction D1 between the center of the light emitting portion 132 and one end portion of the optical member 102 is different from the distance between the center of the light emitting portion 132 and the other end portion of the optical member 102. In this case, to enhance light utilization efficiency, the light emitting portion 132 may have a line-symmetric shape with only one symmetry axis, or the light emitting portion 132 may have a shape without rotational symmetry.

For example, in a case where the light emitting device 100 is incorporated in the display device such as a head mounted display for which the light emitting device 100 is worn near the eyeball of the user, the visible field of view may be changed between the vertical direction and the lateral direction. For example, the human eye can view a wider range in the lateral direction than in the vertical direction, and therefore, a higher viewing angle characteristic may be required in the lateral direction than in the vertical direction. In this case, by using the optical member 102, light from the plurality of light emitting elements 101 is magnified and projected onto, for example, the viewing portion of eyeglasses. In this case, the larger radiation angle is required for the display device in the direction where the visible field of view is larger.

In such a case, even if the length of the optical member 102 in the direction D1 is not shorter than the length in the direction D2, the light emitting portion 132 may be formed to have a shape with the length shorter in the first direction than in the second direction. When incorporating the light emitting device 100 in a display device such as a head mounted display, a pancake lens or the like can be used as the optical member 102. In that case, the optical member 102 may not have the long sides and short sides as shown in FIGS. 1 and 2. Even in this case, by satisfying the above-described relationship of d1/2<d2 expressed by inequality (1), the amount of light having a large radiation angle in the direction D1 can be reduced, thereby reducing power consumption while keeping display quality. In this case, the direction D1 can be set to approximate the vertical direction of the user's line of sight when the user wears the display device such as the head mounted display incorporating the light emitting device 100.

In the present disclosure, one lens 117 and one light emitting portion 132 are provided for each of the plurality of light emitting elements 101 so the plurality of light emitting elements 101 do not share the lens 117 and the light emitting portion 132. It can also be understood that the lens 117 and the light emitting portion 132 are provided in a one-to-one relationship. From another viewpoint, in the orthogonal projection onto the main surface 151 of the substrate 108, one lens 117 overlaps the center of one light emitting portion 132, and does not overlap the centers of two or more light emitting portions 132. In the orthogonal projection onto the main surface 151 of the substrate 108, one lens 117 overlaps the center of one electrode 109, and does not overlap the centers of two or more electrodes 109. To enhance the light extraction efficiency in the normal direction of the main surface 151 of the substrate 108, the vertex 141 of the lens 117 and the center of the light emitting portion 132 may be arranged to overlap in the orthogonal projection onto the main surface 151 of the substrate 108. On the other hand, to enhance the light extraction efficiency in a specific direction, the center of the light emitting portion 132 and the vertex 141 may be arranged while being shifted from each other. In the light emitting region of the light emitting device 100 where the plurality of light emitting elements 101 are arranged, the center of the light emitting portion 132 and the vertex 141 may be arranged while being shifted from each other in the same direction in the whole region of the light emitting region. Alternatively, the center of the light emitting portion 132 and the vertex 141 may be arranged to overlap each other near the center of the light emitting region, and the shift between the center of the light emitting portion 132 and the vertex 141 may be increased toward the outer periphery of the light emitting region. In this case, the center of the light emitting portion 132 and the vertex 141 may be shifted from each other in a direction toward the outer peripheral portion of the light emitting device.

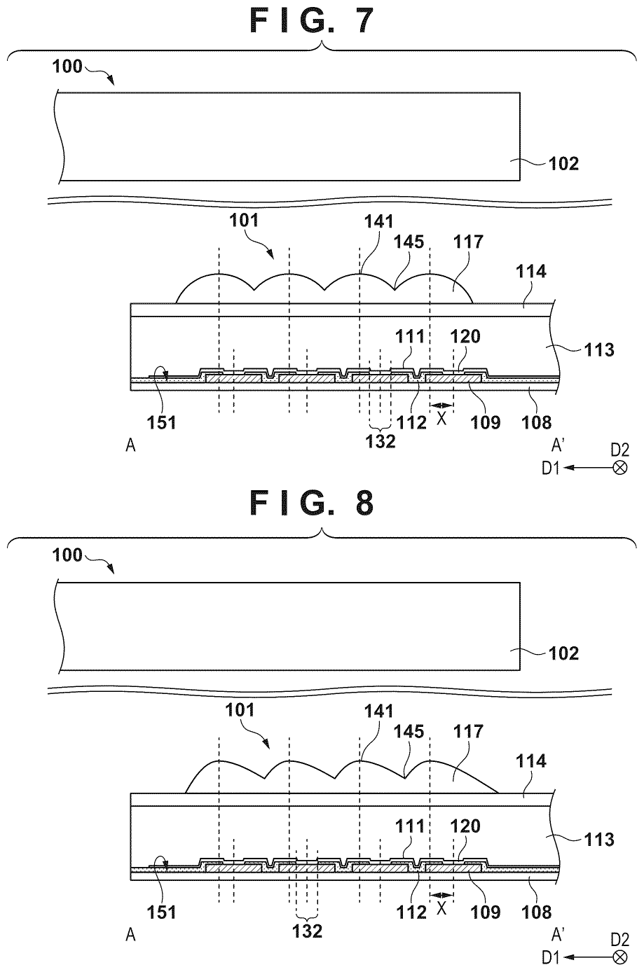

FIGS. 7 and 8 are views each showing a section taken along a line A-A′ in FIG. 1, similar to FIG. 2, in another arrangement example of the light emitting device 100 according to this embodiment. As shown in FIG. 1, when a plurality of substrates 108 are arranged in a staggered pattern, the virtual straight line 137, which is the symmetry axis of the optical member 102 parallel to the direction D2, may not overlap the center of the light emitting portion 132. In this case, the vertex 141 of the lens 117 is arranged to shift in a direction from the center of the light emitting portion 132 toward the virtual straight line 137 as the symmetry axis of the optical member 102 parallel to the direction D2. With this, the light utilization efficiency in the optical member 102 may be improved. Accordingly, in the orthogonal projection onto the main surface 151 of the substrate 108, the vertex 141 of the lens 117 may be arranged spaced apart from the center of the light emitting portion 132 by a first distance in one direction (toward the virtual straight line 137 as the symmetry axis of the optical member 102 parallel to the direction D2) of the direction D1. In this case, in the orthogonal projection onto the main surface 151 of the substrate 108, the center of the optical member 102 in the direction D1 is arranged spaced apart from the center of the light emitting portion 132 by a second distance larger than the first distance in one direction (toward the virtual straight line 137 as the symmetry axis of the optical member 102 parallel to the direction D2) of the direction D1. In other words, in the orthogonal projection onto the main surface 151 of the substrate 108, the distance in the direction D1 between the center of the light emitting portion 132 and the vertex 141 of the lens 117 in the light emitting element 101 is shorter than the distance in the direction D1 between the center of the light emitting portion 132 and the center of the optical member 102.

Similarly, to improve the light utilization efficiency in the optical member 102, in the orthogonal projection onto the main surface 151 of the substrate 108, the center of the pad 134 is arranged spaced apart from the center of the light emitting portion 132 by the third distance larger than the first distance in the other direction (opposite to the direction toward the virtual straight line 137 as the symmetry axis of the optical member 102 parallel to the direction D2) of the direction D1. That is, as shown in FIG. 1, in the orthogonal projection onto the main surface 151 of the substrate 108, the center of the light emitting portion 132 is arranged between the center of the optical member 102 and the center of the pad 134 in the first direction.

Here, a distance X in the direction D1 between the center of the light emitting portion 132 and the vertex 141 of the lens may be constant among the plurality of light emitting elements 101. Alternatively, to improve the light utilization efficiency, the distance X in the direction D1 between the center of the light emitting portion 132 and the vertex 141 of the lens may be changed in accordance with the distance from the virtual straight line 137 as the symmetry axis of the optical member 102 parallel to the direction D2. In the arrangements shown in FIGS. 7 and 8, the distance X in the direction D1 between the center of the light emitting portion 132 and the vertex 141 of the lens increases as the distance between the light emitting element 101 and the virtual straight line 137 increases.

In the case where the center of the light emitting portion 132 and the vertex 141 of the lens 117 are arranged while being shifted from each other, the shape of the lens 117 may be a part of an approximately spherical surface, as shown in FIG. 7. Alternatively, the shape of the lens 117 may have an asymmetric curvature, as shown in FIG. 8.

A more specific arrangement example of the light emitting device 100 will be described here. As shown in FIG. 2, the light emitting device 100 can include the substrate 108, the electrodes 109, the organic layer 120, the electrode 111, the insulating layer 112, the protective layer 113, the planarizing layer 114, and the lenses 117. In this embodiment, each of the electrode 109 and the electrode 111 may function as a reflective layer that reflects light as will be described later.

The electrode 109 is arranged on the main surface of the substrate 108. The electrode 109 can also be referred to as a lower electrode. The organic layer 120 includes a light emitting layer containing a light emitting material. A part of the organic layer 120 (light emitting layer) functions as the light emitting portion 132 described above. The organic layer 120 is arranged between the substrate 108 and the lens 117 to cover the electrodes 109. The electrode 111 is arranged on the organic layer 120. The electrode 111 can also be referred to as an upper electrode. The light emitting layer is included in the organic layer 120, and emits light according to the potential difference between the electrode 109 and the electrode 111.

The insulating layer 112 is arranged between the adjacent electrodes 109 so as to insulate the adjacent electrodes 109 from each other. The insulating layer 112 can also be called a bank. The insulating layer 112 is arranged, for example, on the electrode 109 in the outer edge portion of the electrode 109. The exposed portion of each electrode 109, that is not covered with the insulating layer 112, is in contact with the organic layer 120. A portion of the organic layer 120, that is in contact with the electrode 109, can be the light emitting portion 132 described above. Therefore, as shown in FIG. 2, a plurality of light emitting portions 132 corresponding to the plurality of electrodes 109, respectively, can be arranged in the light emitting device.

The protective layer 113 is arranged on the electrode 111, and the planarizing layer 114 is arranged on the protective layer 113. The lenses 117 are arranged on the planarizing layer 114. The lenses 117 are arranged to respectively correspond to the electrodes 109.

A material used for the substrate 108 is not particularly limited as long as the material can support the respective components of the light emitting device, such as the electrodes 109, the organic layer 120, and the electrode 111. For example, glass, plastic, or silicon may be used as the material of the substrate 108. A switching element such as a transistor, a wiring pattern, an interlayer insulating film, and the like may be provided on the main surface 151 of the substrate 108.

The electrodes 109 can be arranged to respectively correspond to the light emitting elements 101. The electrode 109 may be transparent or opaque to light emitted from the light emitting portion 132. If the electrode 109 is opaque, the material of the electrode 109 may be a metal material whose reflectance of the wavelength of light emitted from the light emitting portion 132 is 70% or more. For example, as the material of the electrode 109, a metal such as aluminum (Al) or silver (Ag), or an alloy obtained by adding silicon (Si), copper (Cu), nickel (Ni), neodymium (Nd), or the like to Al or Ag may be used. Alternatively, the electrode 109 may be a transparent electrode made of ITO, IZO, AZO, IGZO, or the like. In this case, the electrode 109 and a reflective layer opaque to light emitted from the light emitting portion 132 can be stacked. The electrode 109 may be a stacked electrode with a barrier electrode made of a metal such as titanium (Ti), tungsten (W), molybdenum (Mo), or gold (Au), or an alloy thereof, or a stacked electrode with a transparent oxide film electrode made of ITO, IZO, or the like as long as the required reflectance is obtained. To optimize an optical distance (to be described later), the electrode 109 may employ an arrangement in which an insulating film is provided between the reflective layer and a transparent conductive film.

The electrode 111 may be a semi-transmissive electrode having a characteristic (that is, a transflective property) of transmitting part of light that has reached the electrode 111 and reflecting the remaining part of the light. As the material of the electrode 111, for example, a transparent material such as a transparent conductive oxide may be used. As the material of the electrode 111, a semi-transmissive material of a single metal (Al, Ag, Au, or the like), an alkali metal (lithium (Li), cesium (Cs), or the like), an alkali earth metal (magnesium (Mg), calcium (Ca), barium (Ba), or the like), or an alloy material containing these metal materials may be used. If a semi-transmissive material is used as the material of the electrode 111, an alloy containing Mg or Ag as a main component may be used as a semi-transmissive material. The electrode 111 may have a stacked structure including a plurality of layers made of the above-described materials as long as it has an appropriate transmittance. In the arrangement shown in FIG. 2, the electrode 111 common to the plurality of light emitting portions 132 is provided. However, the present disclosure is not limited to this, and a plurality of electrodes 111 respectively corresponding to the plurality of light emitting portions 132 may be arranged.

One of the electrode 109 and the electrode 111 functions as an anode, and the other functions as a cathode. For example, the electrode 109 may function as an anode and the electrode 111 may function as a cathode. Alternatively, for example, the electrode 109 may function as a cathode and the electrode 111 may function as an anode.

The organic layer 120 can be formed by a known technique such as a deposition method or a spin coating method. The organic layer 120 may be formed from a plurality of layers. If the organic layer 120 is an organic compound layer, the organic layer 120 may include at least one of a hole injection layer, a hole transport layer, an electron blocking layer, a hole blocking layer, an electron transport layer, an electron injection layer, and the like in addition to the light emitting layer.

The light emitting layer emits light when holes injected from the anode and electrons injected from the cathode are recombined in the light emitting layer. The light emitting layer may include a single layer or a plurality of layers. If, for example, a light emitting layer containing a red light emitting material, a light emitting layer containing a green light emitting material, and a light emitting layer containing a blue light emitting material are combined, light beams (red light, green light, and blue light) from the respective light emitting layers can be mixed to obtain white light. Two kinds of light emitting layers whose light emission colors have a complimentary color relationship (for example, a light emitting layer containing a blue light emitting material and a light emitting layer containing a yellow light emitting material) may be combined. In the light emitting device 100 shown in FIG. 2, the light emitting portions 132 emit light of the same color. However, the present disclosure is not limited to this. A material contained in a light emitting layer and the arrangement of the light emitting layer may be different for each light emitting portion 132 so that the light emitting layer emits light of a different color for each light emitting portion 132. In this case, the light emitting layer may be patterned for each light emitting portion 132.

The light emitting device 100 may have a so-called tandem structure in which the organic layer 120 includes a plurality of light emitting layers and a charge generating layer arranged between the plurality of light emitting layers. By having the tandem structure, the plurality of light emitting layers emit light at the same time, thereby improving light emission efficiency.

Here, a description will be given assuming that the electrode 109 reflects light emitted from the light emitting portion 132. In this case, to optimize the optical distance between the first reflective surface as the surface of the electrode 109 and the light emission position of the organic layer 120 including the light emitting layer, it is sufficient that equation (2) below be satisfied. In equation (2), Lᵣ represents an optical path length (optical distance) from the first reflective surface as the surface of the electrode 109 to the light emission position of the organic layer 120. Φᵣ represents a phase shift when light of a wavelength λ is reflected by the first reflective surface, and takes a value of −π or more and 0 or less. m is an integer of 0 or more. The film thickness between the electrode 109 and the organic layer 120, the film thickness of each layer of the organic layer 120, and the like may be designed so as to satisfy equation (2).

$${L}_{r} = ( 2 \times m - ( {Φ}_{r} / π ) ) \times ( λ / 4 ) \qquad ( 2 )$$

Furthermore, if Φₛ represents a phase shift when light of the wavelength λ is reflected by the second reflective surface, and m₂ is an integer of 0 or more, an optical distance Lₛ from the light emission position to the second reflective surface as the lower surface of the electrode 111 needs to satisfy equation (3) below. Here, (s takes a value of −π or more and 0 or less.

$${L}_{s} = ( 2 \times {m}_{2} - ( {Φ}_{s} / π ) ) \times ( λ / 4 ) \qquad ( 3 )$$

Therefore, a whole layer interference L needs to satisfy equation (4) below. In equation (4), (represents a sum of the phase shift Φᵣ and the phase shift Φₛ, and m₃ is an integer of 0 or more.

$$L = {L}_{r} + {L}_{s} = ( 2 \times {m}_{3} - Φ / π ) \times ( λ / 4 ) \qquad ( 4 )$$

In this example, in equations (2) to (4) above, an allowable range is about λ/8 or about 20 nm. Since it may be difficult to specify the light emission position in the organic layer 120, the interface on the first reflective surface side or the second reflective surface side of the light emitting layer of the organic layer 120 is used instead of the light emission position in the above example. In consideration of the above-described allowable range, even if the interface is used instead, an effect of intensifying light can be obtained.

The protective layer 113 is a dielectric layer. The protective layer 113 has a transmissive property that allows light emitted from the light emitting portion 132 to pass therethrough. Furthermore, the protective layer 113 may contain an inorganic material having a low permeability for oxygen and water from the outside of the light emitting device. For example, the protective layer 113 may be formed using an inorganic material such as silicon nitride (SiN), silicon oxynitride (SiON), silicon oxide (SiOₓ), aluminum oxide (Al₂O₃), or titanium oxide (TiO₂). In terms of the protection performance, the protective layer 113 may be made of an inorganic material such as SiN, SiON, or Al₂O₃. A chemical vapor deposition (CVD) method, an atomic layer deposition (ALD) method, a sputtering method, or the like can be used to form the protective layer 113.

The protective layer 113 can have a single-layer structure using the above-described material or a stacked structure using the above-described materials in combination as long as the protective layer 113 has sufficient water block performance. For example, the protective layer 113 may have a stacked structure of a layer of SiN formed using the CVD method and another layer (for example, Al₂O₃) having a high density formed using the ALD method. Furthermore, the protective layer 113 may include an organic layer as long as it has water block performance. For example, polyacrylate, polyimide, polyester, epoxy, or the like can be used for the organic layer. In addition, in the arrangement shown in FIG. 2, the protective layer 113 common to the plurality of light emitting portions 132 is provided but a plurality of protective layers 113 respectively corresponding to the plurality of light emitting portions 132 may be arranged.

The planarizing layer 114 is provided to planarize unevenness of the surface of the protective layer 113. The planarizing layer 114 may be formed of an inorganic material such as silicon oxide, or may be formed of an organic material such as various resins, or may have a stacked structure of these. If the surface of the protective layer 113 has a flatness required for, for example, formation of the lens 117 or the like, the planarizing layer 114 may not be arranged.

The lens 117 can be formed using an exposure process and a developing process. More specifically, a material film (for example, a photoresist film) of the lens 117 is formed, and the photoresist film is exposed and developed using a mask including a continuous change in gradation. As the mask used to form the lens 117, a gray mask can be used. An area gradation mask that allows light irradiation with a continuous change in gradation on the imaging plane by changing the density distribution of dots of a light shielding film with a resolution equal to or lower than the resolution of an exposure device can be used as the mask used to form the lens 117. The lens shape can be adjusted by etching back the lens 117 formed by the exposure process and the developing process. As describe above, the surface of the lens 117 has a convex shape in a direction away from the main surface of the substrate 108. The surface shape of the lens 117 may be a part of a spherical surface (circle), or may be aspherical.

The light emitting element 101 is formed by a combination of the light emitting portion 132 and the lens 117. If a plurality of light emitting elements 101 are provided, the planar arrangement (the arrangement when viewed from the normal direction of the main surface of the substrate 108) of the plurality of light emitting elements 101 may be any of a stripe arrangement, a square arrangement, a delta arrangement, a pentile arrangement, and a Bayer arrangement. Here, consider a case where the light emitting device 100 is used as a display panel, and one pixel (main pixel) includes a plurality of sub-pixels having different corresponding color components (for example, a sub-pixel that performs red display, a sub-pixel that performs green display, and a sub-pixel that perform blue display). In this case, the plurality of light emitting elements 101 may constitute one pixel. An arrangement in which the lenses 117 transmit light beams of different colors may be adopted. With this, the light emitting device can perform full-color display. As a method of implementing full-color display, a method of using the color filters and the light emitting layer that emits white light may be adopted. If the color filters are used, since the plurality of light emitting portions 132 can share the light emitting layer, a manufacturing process of the light emitting layer is easier than in a case where the light emitting layer is patterned to emit light of a different color for each light emitting portion 132. However, the light emitting layer may be patterned so that the plurality of light emitting portions 132 emit light beams of different colors. Furthermore, the above-described optical path length L (the optical path length Lᵣ or Lₛ) between the first reflective layer and the second reflective layer may be different for each of the light emitting portions 132 that emit light beams of different colors.

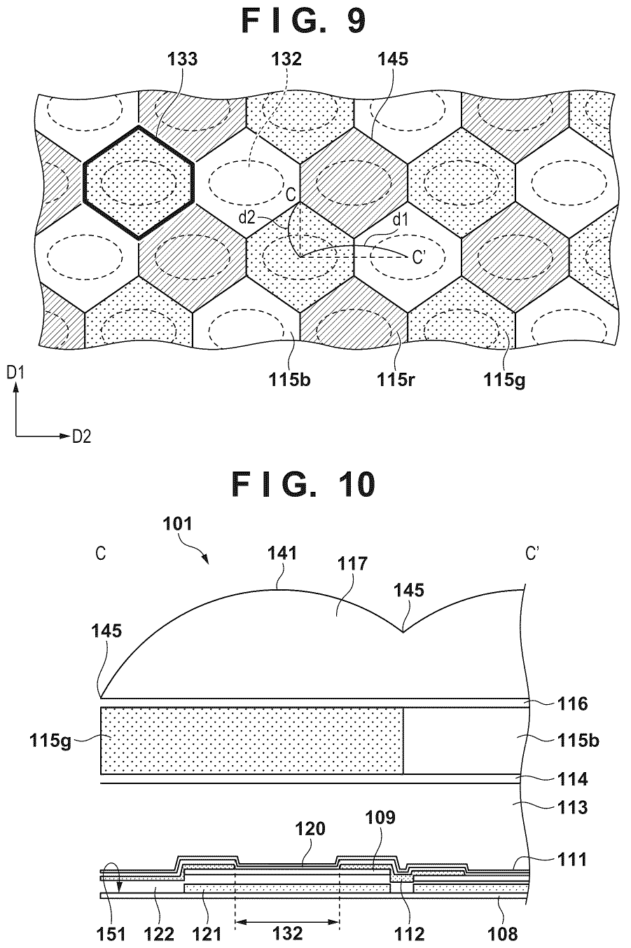

FIGS. 9 and 10 show an example of the light emitting device 100 according to the present disclosure in a case where the pixels are arranged in a delta arrangement and sub-pixels as three kinds of unit pixels 133 for performing red display, green display, and blue display are provided. FIG. 9 is an orthogonal projection view when viewed from a direction perpendicular to the main surface 151 of the substrate 108, and FIG. 10 is a sectional view taken along a line C-C′ in FIG. 9.

In the arrangement shown in FIG. 9, the unit pixel 133 has a hexagonal shape. FIG. 9 shows one unit pixel 133 with a thick line. The outer edge 145 of the lens 117 matches the outer edge of the unit pixel 133. Since the area of the unit pixel 133 occupied by the lens 117 can be increased, the light extraction efficiency can be improved.

In the arrangement shown in FIGS. 9 and 10, color filters 115 are provided on the planarizing layer 114. However, the present disclosure is not limited to this, and the color filters 115 may be provided on the protective layer 113. For example, the color filters 115 and the protective layer 113 may be arranged to contact each other without arranging the planarizing layer 114. Alternatively, for example, the color filters 115 and the protective layer 113 may be integrated. The color filters 115 may be formed on a support substrate different from the substrate 108 and this substrate may be bonded so as to oppose the protective layer 113, thereby forming the color filters 115 of the light emitting device 100.

The planarizing layer 114 is provided to planarize unevenness of the surface of the protective layer 113. By arranging the planarizing layer 114, the color filters 115 can be formed to be accurately aligned with the respective light emitting portions 132 using a photolithography process. As described above, by integrating the color filters 115 and the protective layer 113 without arranging the planarizing layer 114, the color filters 115 can be formed to be accurately aligned with the respective light emitting portions 132 using a photolithography process.

In the arrangement shown in FIGS. 9 and 10, color filters 115r, 115g, and 115b may be color filters configured to transmit light beams of different colors. For example, the color filter 115r may transmit red light, the color filter 115g may transmit green light, and the color filter 115b may transmit blue light. Some or all of the plurality of color filters 115 may not be arranged to configure the light emitting device 100 as a device that emits a single light emission color. Alternatively, if the light emitting layer of the organic layer 120 is formed for each light emitting element 101 to differentiate the colors of the light beams emitted from the light emitting portions 132, the light emitting device 100 may be a device that can perform full-color display.

Furthermore, in the arrangement shown in FIGS. 9 and 10, the lenses 117 are provided on the planarizing layer 116. The planarizing layer 116 is provided to planarize unevenness of the surfaces of the color filters 115. However, the lenses 117 may be provided on the color filters 115. In this case, the planarizing layer 116 need not be arranged. Alternatively, the lenses 117 and the color filters 115 may be integrated.

Furthermore, the lenses 117 may be provided on the protective layer 113 without arranging the color filters 115 and the planarizing layers 114 and 116. For example, the lenses 117 and the protective layer 113 may be integrated. If the lenses 117 and the protective layer 113 are integrated, the distance from the lens 117 to the light emitting portion 132 can be shortened, as compared with a case where the lenses 117 are formed on another substrate and this substrate is bonded so as to oppose the protective layer 113. As a result, the solid angle of light entering the lens 117 from the light emitting portion 132 can be increased, thereby improving light extraction efficiency. By integrating the lenses 117 and the protective layer 113, the vertex 141 of each lens 117 can be accurately aligned with the corresponding light emitting portion 132. For example, by integrating the color filters 115, the lenses 117, and the protective layer 113, the light emitting portions 132, the color filters 115, and the lenses 117 can accurately be aligned, respectively.

The stacking order of the color filters 115 and the lenses 117 can appropriately be selected. In the arrangement shown in FIGS. 9 and 10, the color filters 115 are provided on the side of the light emitting portions 132 with respect to the lenses 117. In this arrangement, light emitted from the light emitting portion 132 passes through the color filter 115 before entering the lens 117. Thus, light (light having a large exit angle from the light emitting portion) that causes deterioration of the color purity passes through the color filter 115 over a relatively long distance. Therefore, it is possible to suppress the deterioration of the color purity when observing the light emitting device from the oblique direction.

The light emitting device may be manufactured by forming the color filters 115 and the lenses 117 on a support substrate different from the substrate 108 and bonding the substrate so as to oppose the substrate 108 including the light emitting portions 132. When the color filters 115 and the lenses 117 are formed separately from the organic layer 120 (light emitting layer), the degree of freedom of a processing method (for example, a temperature and the like) when forming the color filters 115 and the lenses 117 improves, thereby making it possible to increase the degree of freedom of the design of the color filters 115 and the lenses 117. The color filters 115 and the lenses 117 may be continuously formed on one support substrate, or the color filters 115 and the lenses 117 may be formed on different support substrates. For example, the lenses 117 and the color filters 115 can be coupled to the substrate 108 using a coupling member such as an adhesive. The coupling member may be arranged on the planarizing layer 114, or may be arranged on the protective layer 113 in a case where the planarizing layer 114 is not arranged.

The lenses 117 may be formed on a support substrate different from the substrate 108 and the substrate may be bonded to oppose the substrate 108 including the light emitting portions 132. In this case, the lenses 117 may be fixed to the substrate 108 by a coupling member such as an adhesive in the end portion of the light emitting device so as to provide a space between the lenses 117 and the protective layer 113 (or the color filters 115). In this case, the space may be filled with a resin. The refractive index of the resin may be lower than a refractive index n₁ of the lens 117.

Alternatively, as shown in FIG. 10, the optical path length (optical distance) may be adjusted in accordance with the color transmitted by the color filter 115 described above. In the arrangement shown in FIG. 10, the electrode 109 transmits light emitted by the light emitting portion 132, and a reflective layer 121 that reflects light emitted by the light emitting portion 132 is arranged between the electrode 109 and the substrate 108. Furthermore, to set the optical path length to an appropriate value, the thickness of a dielectric layer 122 arranged between the electrode 109 and the reflective layer 121 is different among the light emitting elements 101 including the color filters 115 configured to transmit different light components.

Examples and comparative examples of the light emitting device 100 according to this embodiment will be described below.

### Example 1

First, aluminum was formed on the substrate 108, thereby forming a plurality of the electrodes 109 respectively corresponding to the light emitting elements 101. The plurality of electrodes 109 were arranged as shown in the FIG. 2. Next, silicon oxide of a film thickness of 65 nm was formed as a material film of the insulating layer 112 to cover each of the plurality of electrodes 109. In the formed material film, an opening portion was formed in the central portion of each of the plurality of electrodes 109 to expose the electrode 109, thereby forming the insulating layer 112. In the light emitting device of this example, the opening portion that exposes the electrode 109 had an elliptical shape with the major axis of 2.4 μm and the minor axis of 1.2 μm. As described above, the opening portion formed in the insulating layer 112 finally corresponds to the light emitting portion 132. That is, in the orthogonal projection onto the main surface 151 of the substrate 108, the size and shape of the opening portion can match the size and shape of the light emitting portion 132. The light emitting portions 132 were arranged as shown in FIG. 2, and the unit pixel 133 had a square shape as shown in FIG. 3. The distance d1 between the centers of the light emitting portions 132 was 4 μm.

After the insulating layer 112 was formed, the organic layer 120 was formed on the plurality of electrodes 109 and the insulating layer 112. More specifically, a hole injection layer was formed to a thickness of 3 nm by compound 1 (to be described below). On the hole injection layer, a hole transport layer was formed to a thickness of 40 nm by compound 2. On the hole transport layer, a light emitting layer was formed to a thickness of 20 nm such that compound 3 serving as a host material was contained in a weight ratio of 99.8% and compound 4 serving as a light emitting dopant was contained in a weight ratio of 0.2%. Next, on the light emitting layer, a hole blocking layer was formed to a thickness of 35 nm by compound 5. Next, on the hole blocking layer, an electron transport layer was formed to a thickness of 22 nm by compound 6. Next, on the electron transport layer, an electron injection layer was formed to a thickness of 1 nm by lithium fluoride.

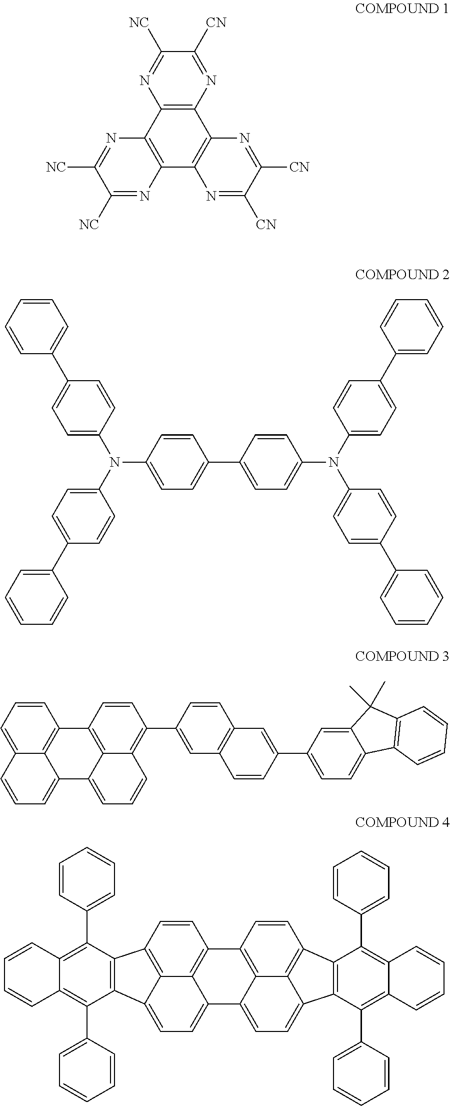

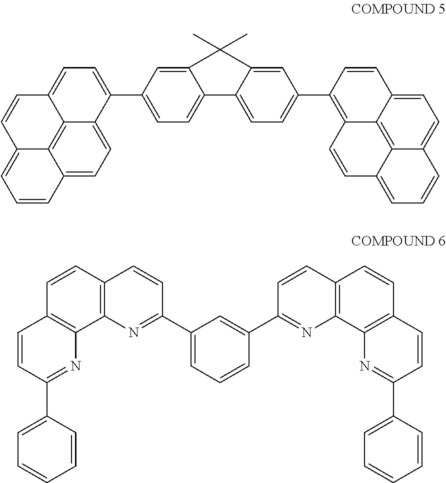

After the organic layer 120 was formed, an Mg/Ag alloy was formed to a thickness of 10 nm as the electrode 111 on the organic layer 120. The ratio of Mg and Ag was 1:1. After that, as the protective layer 113, SiN with a refractive index of 1.97 was formed to a thickness of 2.0 μm on the electrode 111 by the CVD method. Next, the planarizing layer 114 with a refractive index of 1.55 was formed to a thickness of 0.2 μm on the protective layer 113 by the spin coating method.

Next, the lens 117 with a refractive index of 1.52 was formed on the planarizing layer 114 using an exposure process and a developing process. The lens 117 was formed to have a shape being a part of an approximately spherical surface. In a planar view from a direction perpendicular to the main surface of the substrate, the outer edge 145 of the lens 117 had a circular shape with a radius of 2 μm.

An erect equal-magnification lens array was provided as the optical member 102 on a plurality of substrates 108 arranged in a staggered pattern as shown in FIG. 1. In the orthogonal projection onto the main surface 151 of the substrate 108, the outer shape of the optical member 102 was a rectangle with short sides of 1 mm and long sides of 420 mm. The distance between the optical member 102 and the vertex 141 of the lens 117 of the light emitting element 101 in a direction perpendicular to the main surface 151 of the substrate 108 was 4 mm. The direction of the short side of the optical member 102 and the direction of the minor axis of the light emitting portion 132 were parallel (direction D1), and the direction of the long side of the optical member 102 and the direction of the major axis of the light emitting portion 132 were parallel (direction D2).

### Comparative Example 1

A light emitting device of a comparative example was formed to have the same arrangement as the light emitting device 100 described in Example 1 except for the shape of the opening portion for exposing the electrode 109, which was a circular shape with a radius of 1.2 μm. Comparing the area of the light emitting portion 132 between the light emitting device 100 of Example 1 and the light emitting device of Comparative Example 1, the area is twice as large in Comparative Example 1.

In a case where the amount of light transmitted through the optical member 102 was the same between the light emitting device 100 of Example 1 and the light emitting device of Comparative Example 1, the power consumption of the light emitting device of Comparative Example 1 was 1.95 times as large as that of the light emitting device 100 of Example 1. The light emitting device 100 having the arrangement according to this example was able to reduce power consumption compared to the light emitting device of the comparative example.

### Example 2

The light emitting device 100 of Example 2 was formed to have the same arrangement as the light emitting device 100 described in Example 1 except for the shape of the outer edge of the lens 117, which was a square with sides of 4 μm in the orthogonal projection onto the main surface 151 of the substrate 108. In this example, the outer edge 145 of the lens 117 matches the outer edge of the unit pixel 133 in the orthogonal projection onto the main surface 151 of the substrate 108.

In a case where the amount of light transmitted through the optical member 102 was the same between the light emitting device 100 of Example 2 and the light emitting device 100 of Example 1, the power consumption of the light emitting device 100 of Example 2 was 0.80 times as large as that of the light emitting device 100 of Example 1. By increasing the area of the lens 117 in the unit pixel 133, power consumption was further reduced.

### Comparative Example 2

A light emitting device of Comparative Example 2 was formed to have the same arrangement as the light emitting device described in Comparative Example 1 except for the shape of the outer edge 145 of the lens 117, which was a square with sides of 4 μm in the orthogonal projection onto the main surface 151 of the substrate 108. In this comparative example, the outer edge 145 of the lens 117 matches the outer edge of the unit pixel 133 in the orthogonal projection onto the main surface 151 of the substrate 108.

In a case where the amount of light transmitted through the optical member 102 was the same between the light emitting device of Comparative Example 2 and the light emitting device 100 of Example 1 described above, the power consumption of the light emitting device of Comparative Example 2 was 1.56 times as large as that of the light emitting device 100 of Example 1. Accordingly, appropriately adjusting the shape of the light emitting portion 132 can effectively reduce power consumption in the light emitting device 100.

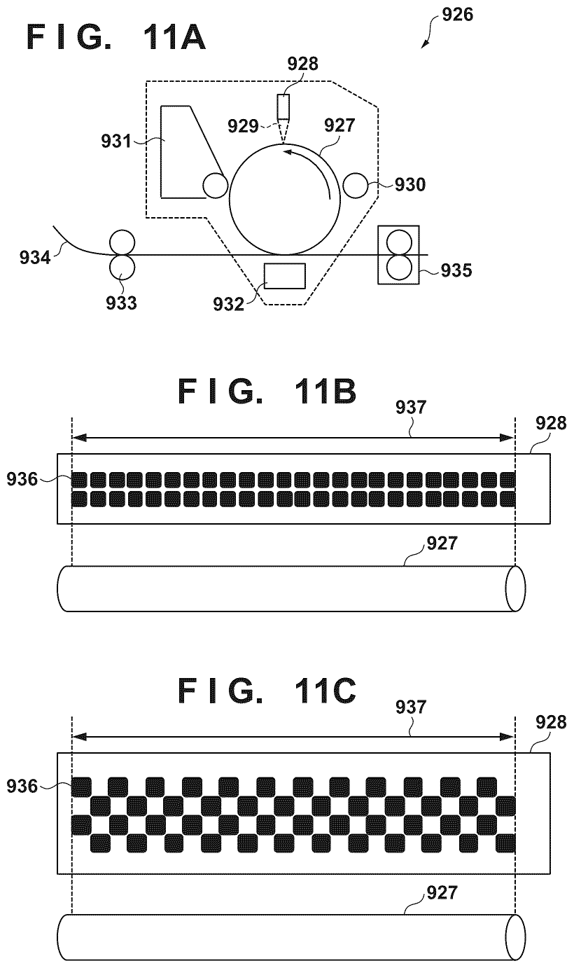

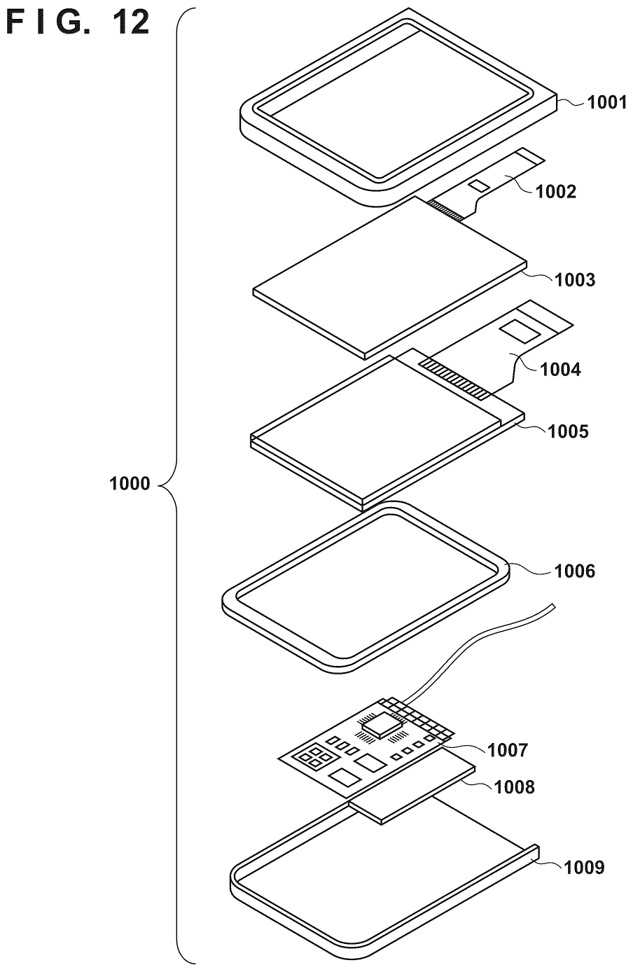

Here, application examples in which the light emitting device 100 according to this embodiment is applied to an image forming device, a display device, a photoelectric conversion device, an electronic apparatus, an illumination device, a moving body, and a wearable device will be described with reference to FIGS. 11A to 18B.

FIGS. 11A to 11C are schematic views showing an example of an image forming device using the light emitting device 100 according to this embodiment. An image forming device 926 shown in FIG. 11A includes a photosensitive member 927, an exposure light source 928, a developing unit 931, a charging unit 930, a transfer device 932, a conveyance unit 933 (a conveyance roller in the arrangement shown in FIG. 11A), and a fixing device 935.

Light 929 is emitted from the exposure light source 928, and an electrostatic latent image is formed on the surface of the photosensitive member 927. The light emitting device 100 can be applied to the exposure light source 928. The developing unit 931 can function as a developing device that includes a toner or the like as a developing agent and applies the developing agent to the exposed photosensitive member 927. The charging unit 930 charges the photosensitive member 927. The transfer device 932 transfers the developed image to a print medium 934. The conveyance unit 933 conveys the print medium 934. The print medium 934 can be, for example, paper, a film, or the like. The fixing device 935 fixes the image formed on the print medium.

Each of FIGS. 11B and 11C is a schematic view showing a form in which a plurality of light emitting portions 936 are arranged in the exposure light source 928 along the longitudinal direction of a long substrate. The light emitting device 100 can be applied to each of the light emitting portions 936. That is, the plurality of light emitting elements 101 (unit pixels 133) are arranged along the longitudinal direction of the substrate. A direction 937 is a direction parallel to the axis of the photosensitive member 927. This column direction matches the direction of the axis upon rotating the photosensitive member 927. This direction 937 can also be referred to as the long-axis direction of the photosensitive member 927.

FIG. 11B shows a form in which the light emitting portions 936 are arranged along the long-axis direction of the photosensitive member 927. FIG. 11C shows a form, which is a modification of the arrangement of the light emitting portions 936 shown in FIG. 11B, in which the light emitting portions 936 are arranged in the column direction alternately between the first column and the second column. The light emitting portions 936 are arranged at different positions in the row direction between the first column and the second column. In the first column, the plurality of light emitting portions 936 are arranged apart from each other. In the second column, the light emitting portion 936 is arranged at the position corresponding to the space between the light emitting portions 936 in the first column. Furthermore, in the row direction, the plurality of light emitting portions 936 are arranged apart from each other. The arrangement of the light emitting portions 936 shown in FIG. 11C can be referred to as, for example, an arrangement in a grid pattern, an arrangement in a staggered pattern, or an arrangement in a checkered pattern.

FIG. 12 is a schematic view showing an example of the display device using the light emitting device 100 according to this embodiment. A display device 1000 can include a touch panel 1003, a display panel 1005, a frame 1006, a circuit board 1007, and a battery 1008 between an upper cover 1001 and a lower cover 1009. Flexible printed circuits (FPCs) 1002 and 1004 are respectively connected to the touch panel 1003 and the display panel 1005. Active elements such as transistors are arranged on the circuit board 1007. The battery 1008 is unnecessary if the display device 1000 is not a portable apparatus. Even when the display device 1000 is a portable apparatus, the battery 1008 need not be provided at this position. The light emitting device 100 can be applied to the display panel 1005. The light emitting elements 101 (unit pixels 133) arranged in the light emitting device 100 functioning as the display panel 1005 operate in a state in which they are connected to a control circuit including the active elements such as transistors arranged on the circuit board 1007.

The display device 1000 shown in FIG. 12 can be used for a display unit of a photoelectric conversion device (also referred to as an image capturing device) including an optical unit having a plurality of lenses, and an image sensor for receiving light having passed through the optical unit and photoelectrically converting the light into an electric signal. The photoelectric conversion device can include a display unit for displaying information acquired by the image sensor. In addition, the display unit can be either a display unit exposed outside the photoelectric conversion device, or a display unit arranged in the finder. The photoelectric conversion device can be a digital camera or a digital video camera.

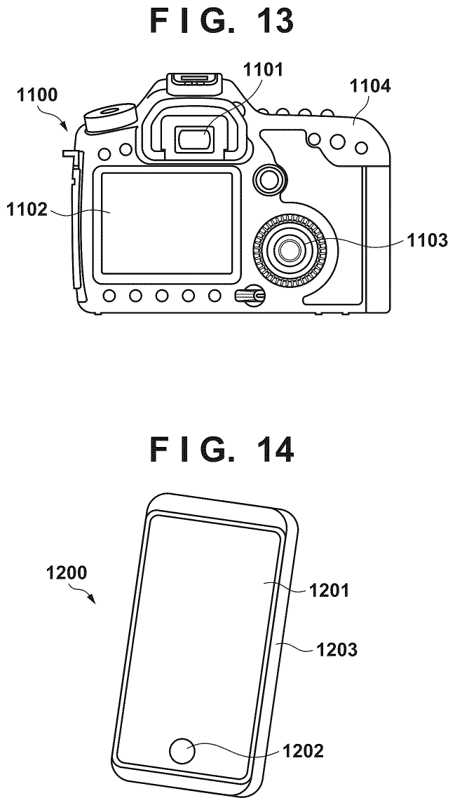

FIG. 13 is a schematic view showing an example of the photoelectric conversion device using the light emitting device 100 according to this embodiment. A photoelectric conversion device 1100 can include a viewfinder 1101, a rear display 1102, an operation unit 1103, and a housing 1104. The photoelectric conversion device 1100 can also be called an image capturing device. The light emitting device 100 according to this embodiment can be applied to the viewfinder 1101 or the rear display 1102 as a display unit. In this case, the light emitting device 100 can display not only an image to be captured but also environment information, image capturing instructions, and the like. Examples of the environment information are the intensity and direction of external light, the moving velocity of an object, and the possibility that an object is covered with an obstacle.

The timing suitable for image capturing is a very short time in many cases, it is better to display the information as soon as possible. Therefore, the light emitting device 100 in which the light emitting elements 101 (unit pixels 133) using the organic light emitting material such as an organic EL element are arranged may be used for the viewfinder 1101 or the rear display 1102. This is so because the organic light emitting material has a high response speed. The light emitting device 100 using the organic light emitting material can be used for the devices that require a high display speed more suitably than for the liquid crystal display device.

The photoelectric conversion device 1100 includes an optical unit (not shown). This optical unit has a plurality of lenses, and forms an image on a photoelectric conversion element (not shown) that receives light having passed through the optical unit and is accommodated in the housing 1104. The focal points of the plurality of lenses can be adjusted by adjusting the relative positions. This operation can also automatically be performed.

The light emitting device 100 may be applied to a display unit of an electronic apparatus. At this time, the display unit can have both a display function and an operation function. Examples of the portable terminal are a portable phone such as a smartphone, a tablet, and a head mounted display.

FIG. 14 is a schematic view showing an example of an electronic apparatus using the light emitting device 100 according to this embodiment. An electronic apparatus 1200 includes a display unit 1201, an operation unit 1202, and a housing 1203. The housing 1203 can accommodate a circuit, a printed board having this circuit, a battery, and a communication unit. The operation unit 1202 can be a button or a touch-panel-type reaction unit. The operation unit 1202 can also be a biometric authentication unit that performs unlocking or the like by authenticating the fingerprint. The portable apparatus including the communication unit can also be regarded as a communication apparatus. The light emitting device 100 according to this embodiment can be applied to the display unit 1201.

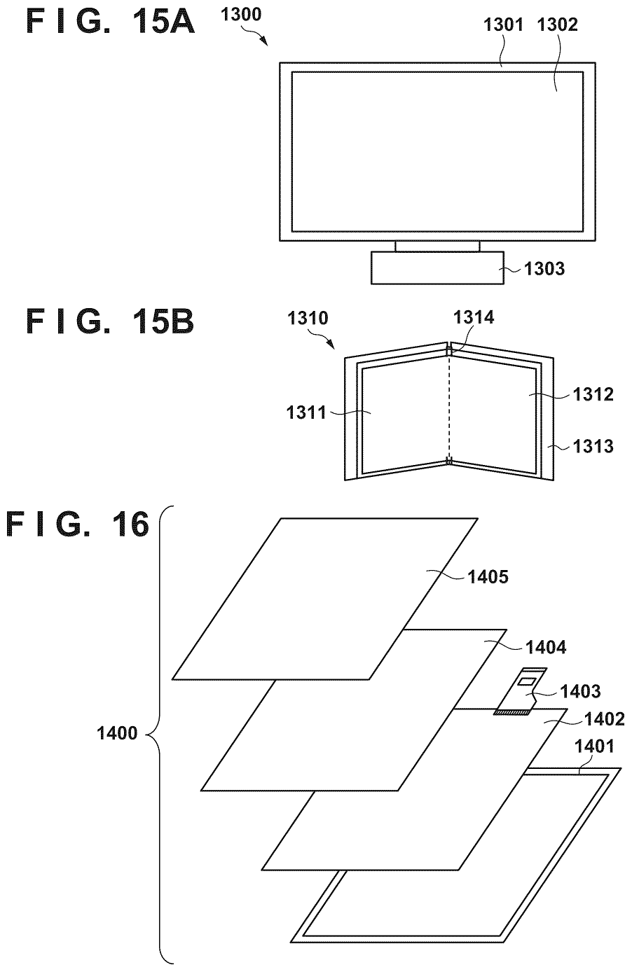

FIGS. 15A and 15B are schematic views showing examples of the display device using the light emitting device 100 according to this embodiment. FIG. 15A shows a display device such as a television monitor or a PC monitor. A display device 1300 includes a frame 1301 and a display unit 1302. The light emitting device 100 according to this embodiment can be applied to the display unit 1302. The display device 1300 can include a base 1303 that supports the frame 1301 and the display unit 1302. The base 1303 is not limited to the form shown in FIG. 15A. For example, the lower side of the frame 1301 may also function as the base 1303. In addition, the frame 1301 and the display unit 1302 can be bent. The radius of curvature in this case can be 5,000 mm (inclusive) to 6,000 mm (inclusive).

FIG. 15B is a schematic view showing another example of the display device using the light emitting device 100 according to this embodiment. A display device 1310 shown in FIG. 15B can be folded, and is a so-called foldable display device. The display device 1310 includes a first display unit 1311, a second display unit 1312, a housing 1313, and a bending point 1314. The light emitting device 100 according to this embodiment can be applied to each of the first display unit 1311 and the second display unit 1312. The first display unit 1311 and the second display unit 1312 can also be one seamless display device. The first display unit 1311 and the second display unit 1312 can be divided by the bending point. The first display unit 1311 and the second display unit 1312 can display different images, and can also display one image together.

FIG. 16 is a schematic view showing an example of the illumination device using the light emitting device 100 according to this embodiment. An illumination device 1400 can include a housing 1401, a light source 1402, a circuit board 1403, an optical film 1404, and a light diffusing unit 1405. The light emitting device 100 according to this embodiment can be applied to the light source 1402. The optical film 1404 can be a filter that improves the color rendering of the light source. When performing lighting-up or the like, the light diffusing unit 1405 can throw the light of the light source over a broad range by effectively diffusing the light. The illumination device can also include a cover on the outermost portion, as needed. The illumination device 1400 can include both or one of the optical film 1404 and the light diffusing unit 1405.

The illumination device 1400 is, for example, a device for illuminating the interior of the room. The illumination device 1400 can emit white light, natural white light, or light of any color from blue to red. The illumination device 1400 can also include a light control circuit for controlling these light components. The illumination device 1400 can also include a power supply circuit connected to the light emitting device 100 functioning as the light source 1402. The power supply circuit is a circuit for converting an AC voltage into a DC voltage. White has a color temperature of 4,200 K, and natural white has a color temperature of 5,000 K. The illumination device 1400 may also include a color filter. In addition, the illumination device 1400 can include a heat radiation unit. The heat radiation unit radiates the internal heat of the device to the outside of the device, and examples are a metal having a high specific heat and liquid silicone.

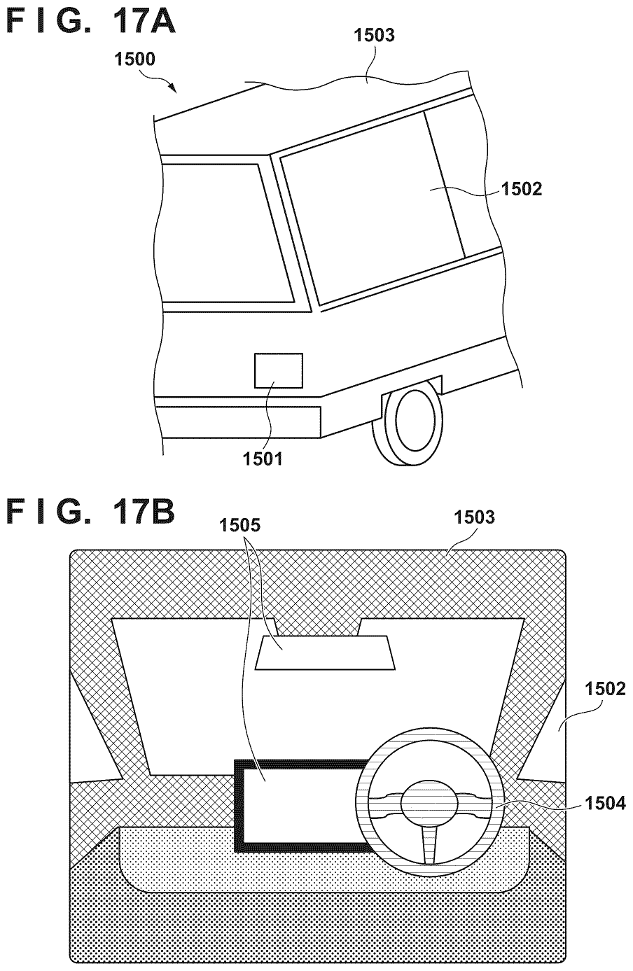

FIG. 17A is a schematic view of an automobile having a taillight as an example of a vehicle lighting appliance using the light emitting device 100 according to this embodiment. An automobile 1500 has a taillight 1501, and can have a form in which the taillight 1501 is turned on when performing a braking operation or the like. The light emitting device 100 according to this embodiment can be used as a headlight serving as a vehicle lighting appliance.

The light emitting device 100 according to this embodiment can be applied to the taillight 1501. The taillight 1501 can include a protection member for protecting the light emitting device 100 functioning as the taillight 1501. The material of the protection member is not limited as long as the material is a transparent material with a strength that is high to some extent, and an example is polycarbonate. The protection member may be made of a material obtained by mixing a furandicarboxylic acid derivative, an acrylonitrile derivative, or the like in polycarbonate.

The automobile 1500 can include a vehicle body 1503, and a window 1502 attached to the vehicle body 1503. This window can be a window for checking the front and back of the automobile, and can also be a transparent display such as a head-up display. For this transparent display, the light emitting device 100 according to this embodiment may be used. In this case, the constituent materials of the electrodes and the like of the light emitting device 100 are formed by transparent members.

As shown in FIG. 17B, the automobile 1500 can include a steering wheel 1504 that controls the moving direction of the moving body (automobile), and a display unit 1505 that is mounted on the vehicle body 1503 and displays a map, the position of the moving body, a turning direction, the visual field on the rear side of the moving body, and the like. The light emitting device 100 according to this embodiment can be applied to the display unit 1505.

The automobile 1500 is an example of the moving body, and the moving body according to this embodiment includes one or both of a driving force generation unit that generates a driving force mainly used for moving the moving body and a rotating body mainly used for moving the moving body. The driving force generation unit can be an engine, a motor, or the like. The rotating body can be a tire, a wheel, a ship screw, an aircraft propeller or fan, or the like. More specifically, the moving body may be a bicycle, an automobile, a train, a ship, an aircraft, a drone, or the like. The moving body may include a main body and a lighting appliance provided in the main body. The lighting appliance may be used to make a notification of the current position of the main body. The lighting appliance may include the light emitting device 100 according to this embodiment. The display unit may include the light emitting device 100 according to this embodiment.

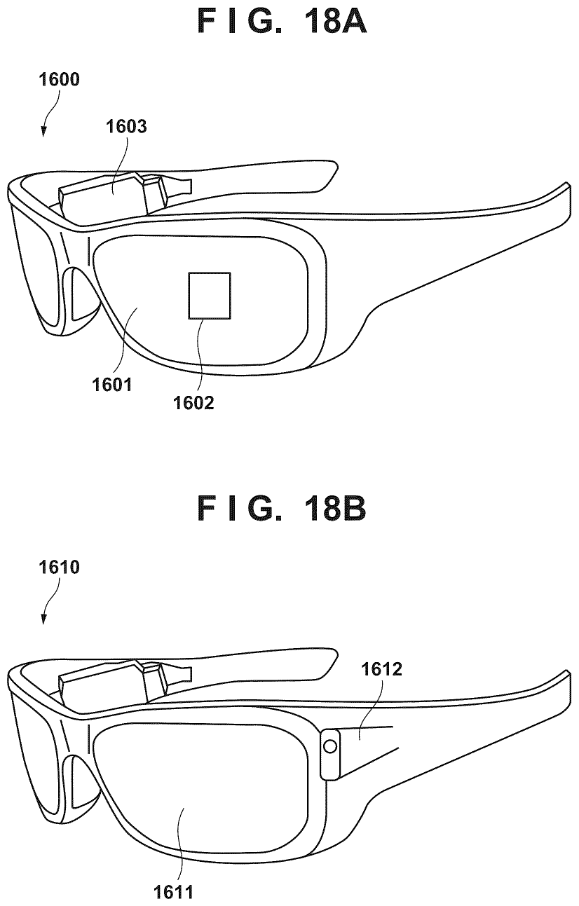

Further application examples of the light emitting device 100 according to this embodiment will be described with reference to FIGS. 18A and 18B. The light emitting device 100 can be applied to a system that can be worn as a wearable device such as smartglasses, a Head Mounted Display (HMD), or a smart contact lens. An image capturing display device used for such application examples includes an image capturing device capable of photoelectrically converting visible light and a light emitting device capable of emitting visible light.

Glasses 1600 (smartglasses) according to one application example will be described with reference to FIG. 18A. An image capturing device 1602 such as a CMOS sensor or an SPAD is provided on the surface side of a lens 1601 of the glasses 1600. In addition, the light emitting device 100 according to this embodiment is provided on the back surface side of the lens 1601.

The glasses 1600 further include a control device 1603. The control device 1603 functions as a power supply that supplies electric power to the image capturing device 1602 and the light emitting device 100 according to each embodiment. In addition, the control device 1603 controls the operations of the image capturing device 1602 and the light emitting device 100. An optical system configured to condense light to the image capturing device 1602 is formed on the lens 1601.

Glasses 1610 (smartglasses) according to one application example will be described with reference to FIG. 18B. The glasses 1610 include a control device 1612, and an image capturing device corresponding to the image capturing device 1602 and the light emitting device 100 are mounted on the control device 1612. The image capturing device in the control device 1612 and an optical system configured to project light emitted from the light emitting device 100 are formed in a lens 1611, and an image is projected to the lens 1611. The control device 1612 functions as a power supply that supplies electric power to the image capturing device and the light emitting device 100, and controls the operations of the image capturing device and the light emitting device 100. The control device 1612 may include a line-of-sight detection unit that detects the line of sight of a wearer. The detection of a line of sight may be done using infrared rays. An infrared ray emitting unit emits infrared rays to an eyeball of the user who is gazing at a displayed image. An image capturing unit including a light receiving element detects reflected light of the emitted infrared rays from the eyeball, thereby obtaining a captured image of the eyeball. A reduction unit for reducing light from the infrared ray emitting unit to the display unit in a planar view is provided, thereby reducing deterioration of image quality.

The line of sight of the user to the displayed image is detected from the captured image of the eyeball obtained by capturing the infrared rays. An arbitrary known method can be applied to the line-of-sight detection using the captured image of the eyeball. As an example, a line-of-sight detection method based on a Purkinje image obtained by reflection of irradiation light by a cornea can be used.

More specifically, line-of-sight detection processing based on pupil center corneal reflection is performed. Using pupil center corneal reflection, a line-of-sight vector representing the direction (rotation angle) of the eyeball is calculated based on the image of the pupil and the Purkinje image included in the captured image of the eyeball, thereby detecting the line-of-sight of the user.

The light emitting device 100 according to the embodiment of the present disclosure can include an image capturing device including a light receiving element, and control a displayed image based on the line-of-sight information of the user from the image capturing device.

More specifically, the light emitting device 100 decides a first visual field region at which the user is gazing and a second visual field region other than the first visual field region based on the line-of-sight information. The first visual field region and the second visual field region may be decided by the control device of the light emitting device 100, or those decided by an external control device may be received. In the display region of the light emitting device 100, the display resolution of the first visual field region may be controlled to be higher than the display resolution of the second visual field region. That is, the resolution of the second visual field region may be lower than that of the first visual field region.

In addition, the display region includes a first display region and a second display region different from the first display region, and a region of higher priority is decided from the first display region and the second display region based on line-of-sight information. The first display region and the second display region may be decided by the control device of the light emitting device 100, or those decided by an external control device may be received. The resolution of the region of higher priority may be controlled to be higher than the resolution of the region other than the region of higher priority. That is, the resolution of the region of relatively low priority may be low.

Note that AI may be used to decide the first visual field region or the region of higher priority. The AI may be a model configured to estimate the angle of the line of sight and the distance to a target ahead the line of sight from the image of the eyeball using the image of the eyeball and the direction of actual viewing of the eyeball in the image as supervised data. The AI program may be held by the light emitting device 100, the image capturing device, or an external device. If the external device holds the Al program, it is transmitted to the light emitting device 100 via communication.

When performing display control based on line-of-sight detection, smartglasses further including an image capturing device configured to capture the outside can be applied. The smartglasses can display captured outside information in real time.

According to the present disclosure, a technique advantageous in reduction of power consumption can be provided.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2025-026029, filed Feb. 20, 2025, which is hereby incorporated by reference herein in its entirety.

What is claimed is:

1. A light emitting device comprising: a substrate; and a light emitting element which is arranged on a main surface of the substrate and includes a light emitting portion including an organic layer and a lens arranged on the light emitting portion,
wherein
the device further comprises, on a light extraction side of the light emitting element, an optical member where light transmitted through the lens enters,
in an orthogonal projection onto the main surface, a length of the optical member in a first direction is shorter than a length of the optical member in a second direction orthogonal to the first direction,
in a virtual section along a normal direction of the main surface and the first direction and passing through a vertex of the lens, a light flux emitted from the light emitting portion and transmitted through the lens includes light rays which enter one end portion and the other end portion, respectively, of the optical member in the first direction, and
in an orthogonal projection onto the main surface, a length of the light emitting portion in the first direction is shorter than a length of the light emitting portion in the second direction.

2. The device according to claim 1, wherein
the optical member includes an erect equal-magnification lens array.

3. The device according to claim 1, wherein
in an orthogonal projection onto the main surface, a length of the optical member passing through a center of the optical member has a minimum value in the first direction, and
in an orthogonal projection onto the main surface, a length of the light emitting portion passing through a center of the light emitting portion has a minimum value in the first direction.

4. The device according to claim 1, wherein
in an orthogonal projection onto the main surface, a difference between a length of the lens in the first direction and a length of the light emitting portion in the first direction is larger than a difference between a length of the lens in the second direction and a length of the light emitting portion in the second direction.

5. The device according to claim 1, wherein
letting d1 be a shortest distance between centers of light emitting portions arranged in light emitting elements adjacent to each other among the plurality of light emitting elements, and d2 be a longest distance from a center in the lens to an outer edge of the lens, a relationship of
d1/2<d2
is satisfied.

6. An image forming device comprising: a photosensitive member; an exposure light source configured to expose the photosensitive member; a developing device configured to apply a developing agent to the exposed photosensitive member; and a transfer device configured to transfer an image developed by the developing device to a print medium,
wherein the exposure light source includes the light emitting device according to claim 1.

7. A wearable device comprising a display device configured to display an image,
wherein the display device includes the light emitting device according to claim 1.

8. A light emitting device comprising: a substrate; and a light emitting element which is arranged on a main surface of the substrate and includes a light emitting portion including an organic layer and a lens arranged on the light emitting portion,
wherein
the device further comprises, on a light extraction side of the light emitting element, an optical member where light transmitted through the lens enters,
an upper surface of the lens has a convex shape toward the optical member,
in an orthogonal projection onto the main surface, a length of the optical member in a first direction is shorter than a length of the optical member in a second direction orthogonal to the first direction, and
in an orthogonal projection onto the main surface, a length of the light emitting portion in the first direction is shorter than a length of the light emitting portion in the second direction.

9. The device according to claim 8, wherein
the optical member includes an erect equal-magnification lens array.

10. The device according to claim 8, wherein
in an orthogonal projection onto the main surface, a length of the optical member passing through a center of the optical member has a minimum value in the first direction, and
in an orthogonal projection onto the main surface, a length of the light emitting portion passing through a center of the light emitting portion has a minimum value in the first direction.

11. The device according to claim 8, wherein
in an orthogonal projection onto the main surface, a difference between a length of the lens in the first direction and a length of the light emitting portion in the first direction is larger than a difference between a length of the lens in the second direction and a length of the light emitting portion in the second direction.

12. The device according to claim 8, wherein
letting d1 be a shortest distance between centers of light emitting portions arranged in light emitting elements adjacent to each other among the plurality of light emitting elements, and d2 be a longest distance from a center in the lens to an outer edge of the lens, a relationship of
d1/2<d2
is satisfied.

13. An image forming device comprising: a photosensitive member; an exposure light source configured to expose the photosensitive member; a developing device configured to apply a developing agent to the exposed photosensitive member; and a transfer device configured to transfer an image developed by the developing device to a print medium,
wherein the exposure light source includes the light emitting device according to claim 8.

14. A wearable device comprising a display device configured to display an image,
wherein the display device includes the light emitting device according to claim 8.

15. Alight emitting device comprising: a substrate, and a plurality of light emitting elements arranged on a main surface of the substrate, each of which includes one light emitting portion and one lens arranged to correspond to the light emitting portion,
wherein
in an orthogonal projection onto the main surface,
a center of the light emitting portion is arranged to overlap the corresponding lens,
a length of the light emitting portion in a first direction is shorter than a length of the light emitting portion in a second direction orthogonal to the first direction, and
in a case where d1 represents a shortest distance between centers of light emitting portions arranged in light emitting elements adjacent to each other among the plurality of light emitting elements, and d2 represents a longest distance from a center in the lens to an outer edge of the lens, a relationship of
d1/2<d2
is satisfied.

16. The device according to claim 15, wherein
in an orthogonal projection onto the main surface, a difference between a length of the lens in the first direction and a length of the light emitting portion in the first direction is larger than a difference between a length of the lens in the second direction and a length of the light emitting portion in the second direction.

17. The device according to claim 15, further comprising, on a light extraction side of the plurality of light emitting elements, an optical member where light transmitted through the lens enters,
wherein, in an orthogonal projection onto the main surface, a length of the optical member in the first direction is shorter than a length of the optical member in the second direction.

18. The device according to claim 17, wherein
in a virtual section along a normal direction of the main surface and the first direction and passing through a vertex of the lens, a light flux emitted from the light emitting portion and transmitted through the lens includes light rays which enter one end portion and the other end portion, respectively, of the optical member in the first direction.

19. An image forming device comprising: a photosensitive member; an exposure light source configured to expose the photosensitive member; a developing device configured to apply a developing agent to the exposed photosensitive member; and a transfer device configured to transfer an image developed by the developing device to a print medium,
wherein the exposure light source includes the light emitting device according to claim 15.

20. A wearable device comprising a display device configured to display an image,
wherein the display device includes the light emitting device according to claim 15.
